(19) United States
(12) Patent Application Publication
(10) Pub. No.: US 2012/0175763 A1
(43) Pub. Date: Jul. 12, 2012

(54) INTEGRATED CIRCUIT PACKAGING INCLUDING AUXILIARY CIRCUITRY

(75) Inventors: PAUL M. HARVEY, AUSTIN, TX (US); ROHAN U. MANDREKAR, AUSTIN, TX (US); SAMUEL W. YANG, AUSTIN, TX (US); YAPING ZHOU, SAN JOSE, CA (US)

(73) Assignee: INTERNATIONAL BUSINESS MACHINES CORPORATION, ARMONK, NY (US)

(21) Appl. No.: 12/985,484

(22) Filed: Jan. 6, 2011

(51) Int. Cl. H01L 23/34; H01L 21/50; H01L 23/522

(52) U.S. Cl. 257/692; 257/774; 438/122; 257/E23.08; 257/E23.142; 257/E21.499

(57) ABSTRACT

An integrated circuit package includes a package core and a primary circuitry chip mounted on the package core. The primary circuitry chip has an active surface in which the core circuitry is fabricated. The active surface of the primary circuitry chip faces the package core and includes contacts. The integrated circuit package further includes an auxiliary circuit chip assembled to the package core and having contacts facing and electrically connected to the contacts of the primary circuitry chip.

### BACKGROUND OF THE INVENTION

1. Technical Field

The present invention relates in general to integrated circuitry, and in particular, to improved packaging for integrated circuitry.

2. Description of the Related Art

High performance processors are typically designed in the latest silicon technology generation to ensure the highest performance at the lowest power. Recent generations of processor designs have incorporated memory and input/output (I/O) interfaces within the processor die to maximize data rates, and thus, system performance. When incorporated into the processor die, memory and I/O interfaces and the associated drivers and receivers consume a significant portion of the total chip area, for example, between twenty and forty percent.

The use of serialization and high speed signaling to improve system performance at reduced system cost also drives I/O design toward the use of more analog integrated circuitry. Good analog IC design depends on stable silicon technology and hardware-validated models. Such stability and validation is almost never available in the state-of-the-art silicon technology primarily utilized for implementation of the digital functionality of the microprocessor core.

The implementation of high speed analog-based I/O also requires that the I/O circuitry be placed in very close proximity to the associated flip chip interconnects (Controlled Collapse Chip Connections (C4s)). The area allocation for I/O is therefore strongly dependent on C4 area requirements, often increasing the area allocation required for the I/O function on the chip. As known in the art, the probabilistic yields and cost for a high performance processor design strongly (and negatively) correlate to chip area.

In view of the significant challenges presented by the design of the I/O interface in the overall processor design process, the IC industry has sought alternatives to the typical processor design and fabrication process in which the I/O function is designed and fabricated on a common die with the processor core and then packaged as a single chip module.

Three viable alternatives to the integration of I/O function into the processor die are presently available:

1. Partitioning the I/O function into a separately packaged I/O bridge chip;

2. Partitioning the I/O and core processor into separate chips positioned side-by-side in a conventional multi-chip module (MCM); and

3. Partitioning the I/O function into a separate chip and stacking the chips vertically and interconnecting them with thru silicon via (TSV) technology.

All of these approaches have significant drawbacks in either cost, performance or both. Partitioning the I/O function into a separately packaged I/O bridge chip requires the cost of an additional package, additional board area and wiring resource to interconnect the two packages, and the power and latency associated with full strength drivers and receivers on both chips. Partitioning the I/O function in a separate chip that is packaged side-by-side together in the same package can potentially reduce some of the ESD requirements associated with the interconnection between the chips in a single module; however, the interconnect lengths are still long enough to require full strength drivers and receivers on each chip, which have significant power and latency penalties. Utilizing a vertical interconnect TSV and stacking the chips directly on top of each other facilitates a short enough interconnect to eliminate most of the power and latency penalties of the interconnect. However, this requires the added processing and design cost associated with fabricating the TSVs in one or both of the chips.

The approach described herein enables partitioning of auxiliary function, such as I/O, into a separate chip that can be packaged in such a way as to facilitate very low power and low latency interconnection without requiring any additional processing of the chips.

### SUMMARY OF THE INVENTION

In some embodiments, an integrated circuit package includes a package and a primary circuitry chip mounted on the package. The primary circuitry chip has an active surface in which the core circuitry is fabricated. The active surface of the primary circuitry chip faces the package and includes contacts. The integrated circuit package further includes an auxiliary circuit chip assembled to the package and having contacts facing and electrically connected to the contacts of the primary circuitry chip vertically thru the package.

### BRIEF DESCRIPTION OF THE DRAWINGS

FIG. 1 is a high level logical flowchart of an exemplary process for realizing an auxiliary function of an integrated circuit design in package-embedded integrated circuit in accordance with one embodiment;

FIG. 2 is a graph depicting the relationship of integrated circuit fabrication yields and fabrication production experience;

FIG. 3 is a high level logical flowchart of a first exemplary process for fabricating and assembling an integrated circuit package incorporating auxiliary integrated circuitry;

FIGS. 4A-4F illustrate the fabrication of an integrated circuit package incorporating auxiliary integrated circuitry in accordance with the first exemplary process shown in FIG. 3;

FIG. 5 is a high level logical flowchart of a second exemplary process for fabricating an integrated circuit package incorporating auxiliary integrated circuitry; and

FIGS. 6A-6F illustrate the fabrication of an integrated circuit package incorporating auxiliary integrated circuitry in accordance with the second exemplary process shown in FIG. 5.

### DETAILED DESCRIPTION OF ILLUSTRATIVE EMBODIMENT

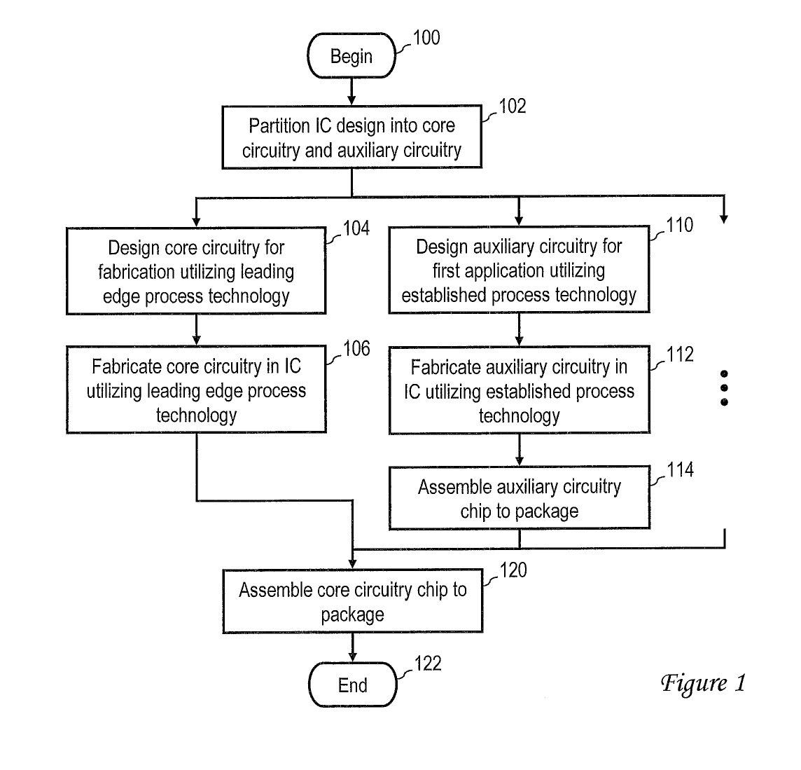

With reference now to the figures and with particular reference to FIG. 1, there is illustrated a high level logical flowchart of an exemplary process for realizing an auxiliary function of an integrated circuit design in package-embedded integrated circuit in accordance with one embodiment. The process begins at block 100 and then proceeds to block 102, which depicts the partitioning of an integrated circuit (IC) design into core circuitry and auxiliary circuitry. In general, functional blocks of the integrated circuit design for which the highest performance and lowest power dissipation are desired or required are designated as the “core circuitry,” while one or more other functional blocks of the integrated circuit design are designated as “auxiliary circuitry.” Taking processor design as an example, the design partitioning illustrated at block 102 may designate the instruction sequencing circuitry, instruction execution circuitry, at least one upper level cache memory, and a system memory interface as the core circuitry of the processor, and may further designate an input/output (I/O) controller of the processor as the auxiliary circuitry. Of course, other divisions of processor circuitry between core circuitry and auxiliary circuitry are possible, and may take into consideration various IC design factors such as die size, power requirements, performance requirements, pin limitations, etc. The partitioning may take into consideration additional human or corporate factors, such as design team size and experience, the planned length of the design cycle, design budget constraints, etc. In various embodiments, the partitioning of the IC design can be performed by human intelligence alone, in an automated fashion by a computer-aided design (CAD) package in response to entry of design factors and/or human and/or corporate factors, or human intelligence aided by automation.

Following the partitioning of the IC design at block 102, the design process itself also likewise divides. In particular, the core circuitry of the IC design is designed and fabricated in a first path as shown at block 104-106. During the design and fabrication of the core circuitry, the auxiliary circuitry of the IC design is designed and fabricated in at least one additional design path as shown, for example, at blocks 110-114. As indicated by elliptical notation, if the IC design is being developed for different end applications, a different version of the auxiliary circuitry may be developed and fabricated for each of the different end application. For example, a first version of the auxiliary circuitry may be developed to implement an I/O function conforming to a first I/O bus standard (e.g., PCI Express), and second version of the auxiliary circuitry may be developed to implement the I/O function in accordance with a different second I/O bus standard (e.g., InfiniBand). Alternatively or additionally, the additional design path(s) represented by the elliptical notation may correspond to multiple different collections of auxiliary circuitry within the IC design. As will be appreciated, with a partitioning of the design into core circuitry and auxiliary circuitry having one or more defined interfaces, the design, fabrication and testing of the core circuitry and auxiliary circuitry can be performed substantially independently, by different design and fabrication teams, and utilizing different process technologies. By decoupling the design of the core circuitry and auxiliary circuitry in this manner, the design process is simplified and accelerated.

Referring specifically to block 104, the core circuitry is typically designed for realization in a leading edge process technology, typically denominated by the minimum size of a critical feature such as the array cell size (e.g., 90 nm, 45 nm, 32 nm, 22 nm, etc.). With the design of the core circuitry complete, the core circuitry design is transmitted, typically in one or more electronic design files, to a fabrication plant (“fab”), which fabricates the integrated circuitry in a first substrate, such as a semiconductor (e.g., Si, SiGe or GaAs) or insulator (e.g., silicon dioxide or sapphire), utilizing the target process technology (block 106). Once the core circuitry design is realized in integrated circuitry (and optionally wafer or die tested), the process passes to block 120, which is described below.

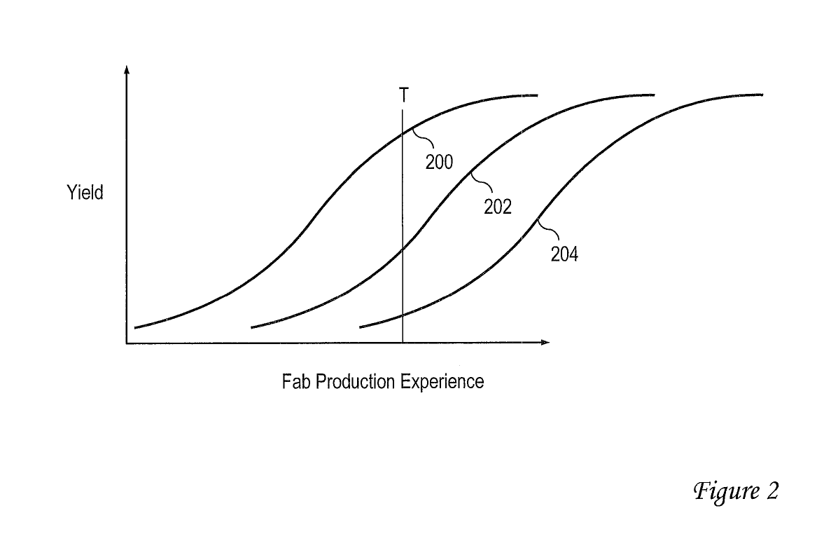

With reference now to block 110, the auxiliary circuitry is typically designed for realization in an established process technology, typically one or two technology generations behind that selected for the primary circuitry. As indicated in FIG. 2, which graphically depicts the relationship of integrated circuit fabrication yields and fabrication production experience with a given process technology, an advantage of selecting an established process technology for the auxiliary circuitry is that yields of chips embodying the auxiliary circuitry design can be substantially higher (and per unit costs are accordingly substantially lower) than if a less mature process technology were adopted. Thus, if the more established process technology associated with curve 200 or curve 202 is adopted for the auxiliary circuitry at time T instead of the leading edge process technology associated with curve 204 (which will be employed for the primary circuitry), the total cost of fabricating the overall design can be significantly reduced.

Returning to FIG. 2, once the design of the auxiliary circuitry at block 110 is completed, the auxiliary circuit design is transmitted, typically in one or more electronic design files, to a fab, which fabricates the integrated circuitry on a second substrate utilizing the target process technology for which the design was developed (block 112). Depending on factors such as material cost, process requirements, and desired material properties, the second substrate in which the auxiliary circuitry is fabricated may be of a different material than the first substrate in which the core circuitry is fabricated.

As depicted at block 114, following fabrication (and optionally wafer or die testing), the auxiliary circuitry chip is assembled to a final IC package, which typically is formed of a ceramic, plastic or flexible film (e.g., polyimide). The primary circuitry chip is also assembled to the package as shown at block 120. While the assembly of the primary circuitry chip and the auxiliary circuitry chip to the package can be performed in any order or substantially concurrently, in many implementations the auxiliary circuitry chip will be fabricated well in advance of the primary circuitry chip and may therefore be preassembled to the package. Following block 120, the process depicted in FIG. 1 ends at block 122.

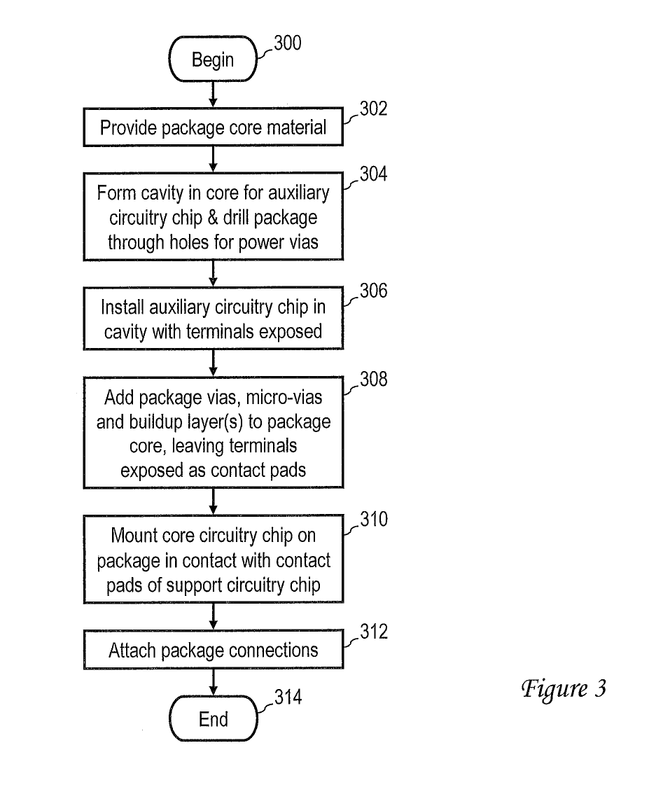

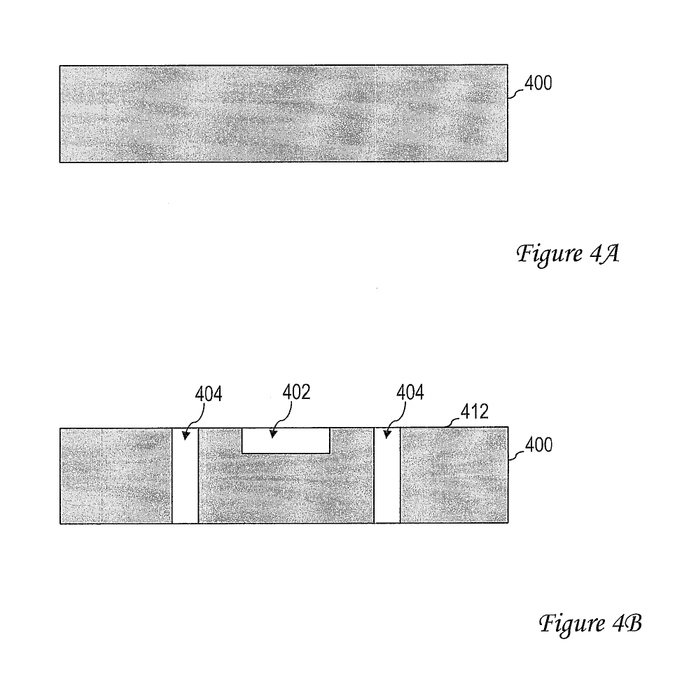

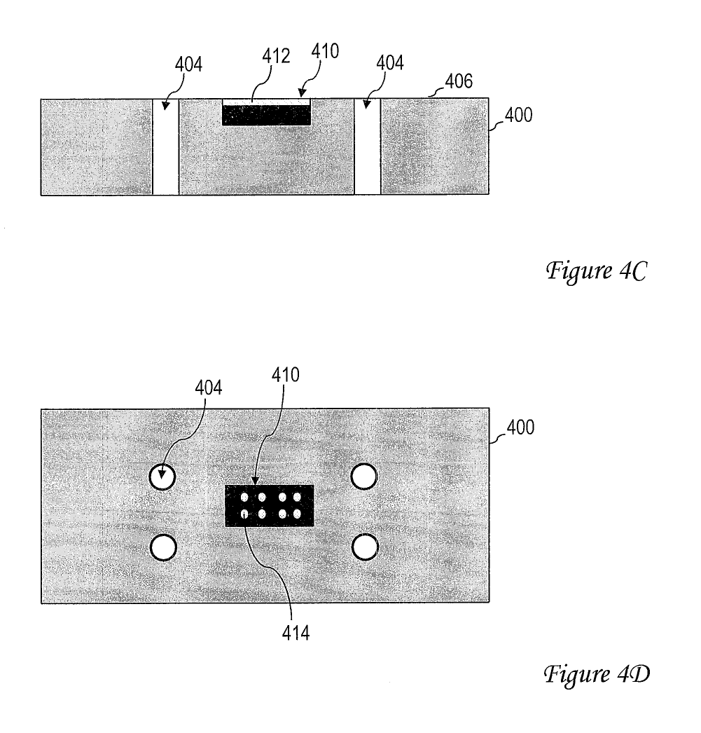

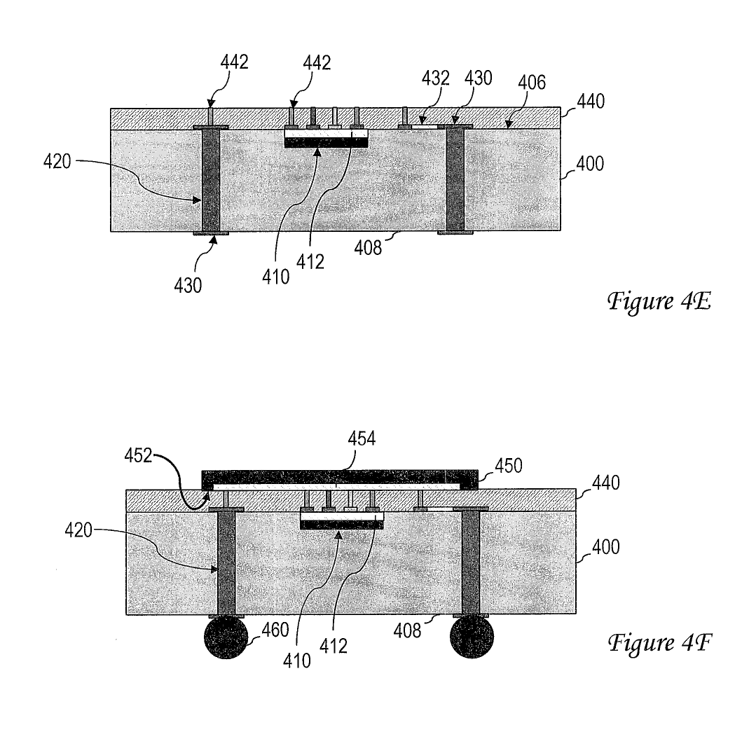

Referring now to FIG. 3, there is depicted a more detailed flowchart of a first exemplary process for fabricating and assembling an integrated circuit package incorporating auxiliary integrated circuitry in accordance with at least one embodiment. The process given in FIG. 3 may be performed, for example, at blocks 114 and 120 of FIG. 1. To promote understanding of the process shown in FIG. 3, the process is described with additional reference to FIGS. 4A-4F, which illustrate an integrated circuit package at various stages of fabrication.

The process of FIG. 3 begins at block 300 and then proceeds to block 302, which illustrates the provision of a package core 400 (shown in section in FIG. 4A), which is typically formed of an insulator like an organic, ceramic or plastic material. Package core 400 can be, for example, around 800 um in thickness or some other thickness that provides a desired package stiffness. At block 304, a cavity 402 is formed in package core 400 by drilling or hogging out a portion of in a first surface 406 of package core 400, as shown in FIG. 4B. In addition, one or more package through holes (PTHs) 404 (e.g., for power vias) are formed through package core 400, for example, by mechanical or laser drilling.

Next, at block 306, the auxiliary circuitry chip 410 is installed in cavity 402 of package core 400, as illustrated in section and plan views in FIGS. 4C and 4D, respectively. As shown, cavity 402 is preferably sized to receive auxiliary circuitry chip 410 such that the surface of auxiliary circuitry chip 410 in which auxiliary circuitry 412 is fabricated is flush with first surface 406 of package core 400. As best seen in FIG. 4D, terminals 414 of the active components are exposed on the surface of auxiliary circuitry chip 410 to provide pads for micro-vias.

As depicted at block 308 and in FIG. 4E, package vias 420 (e.g., for signals and/or power) are then formed in package through holes 404. Contact pads 430 for package vias 420 are formed on second surface 408 of package core 400. In addition, on first surface 406 of package core 400, contact pads 430, and optionally, metallizations 432 are deposited to support connection of micro-vias to terminals 414 of auxiliary circuitry chip 410. Over first surface 406, one or more buildup layer(s) 440, for example, of an insulator such as silicon dioxide, are formed. Through buildup layer(s) 440 vias 442 for formed (e.g., utilizing conventional etching and metallic deposition) to form electrical connections to contact pads 430.

Following block 308, the terminals of vias 442 remain exposed at the surface of buildup layers(s) 440. As depicted in block 310 and in FIG. 4F, primary circuitry chip 450 is then mounted on buildup layer(s) 440. As shown, primary circuitry chip 450 is preferably mounted with the surface 452 in which core circuitry 454 are fabricated facing buildup layers(s) 440 and terminals of the active components 454 are in contact with the terminals of vias 442. In this manner, primary circuitry chip 450 can be supplied with power, ground and signal connections to auxiliary circuitry chip 412 through micro-vias 442 as well as to package vias 420.

Finally, at block 312, package connections 460, such as ball grid array (BGA) or land grid array (LGA) connections are attached to contact pads 430 on second surface 408 of package core 400 in order to provide power, ground and signal connections to an underlying circuit card or circuit board. Thereafter, the process depicted in FIG. 3 ends at block 314.

The process of FIG. 3, while providing advantages for designs having various types of auxiliary circuitry, provides additional advantages for auxiliary circuitry implementing I/O functionality of the design. For example, if auxiliary circuitry 412 implements I/O functionality, then auxiliary circuitry 412 can be implemented with relatively high power signal drivers and receivers to communicate with the circuit card or board to which the package is connected, as well as the associated electrostatic discharge (ESD) protection circuitry needed to protect auxiliary circuitry 412 from damage. Core circuitry on the primary chip 454 accordingly need only include weak drivers/receivers, particularly in view of the extremely short length of micro-vias possible through the vertical stacking of chips 410 and 450. Consequently, the drivers/receivers of core circuitry 454 that communicate signals with auxiliary circuitry 412 can be powered with the base core voltage, potentially reducing the number of power domains needed in primary circuitry chip 450. Further, the size of core circuitry 454 is reduced (and its scalability is improved) because core circuitry 454 need only include minimum ESD protection circuitry.

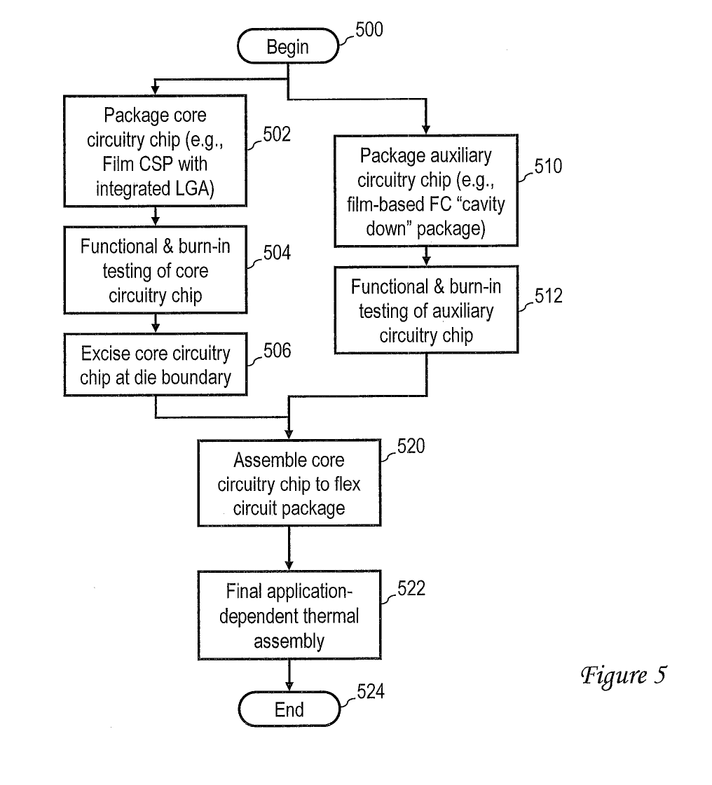

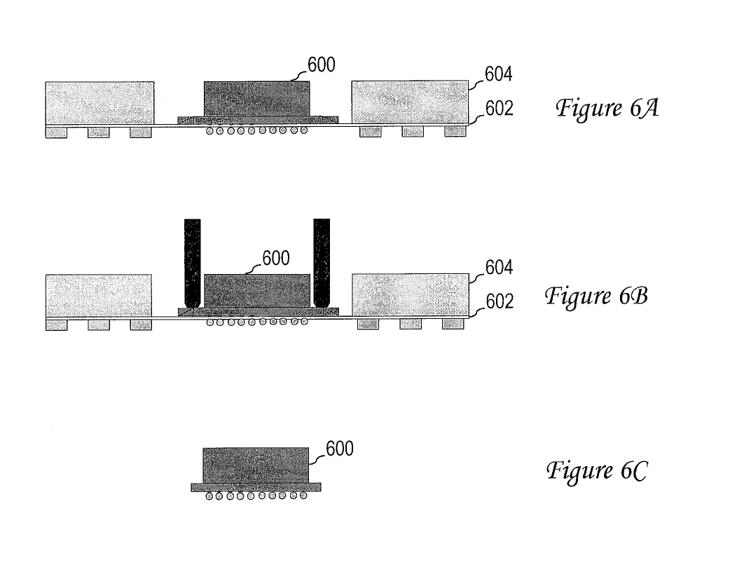

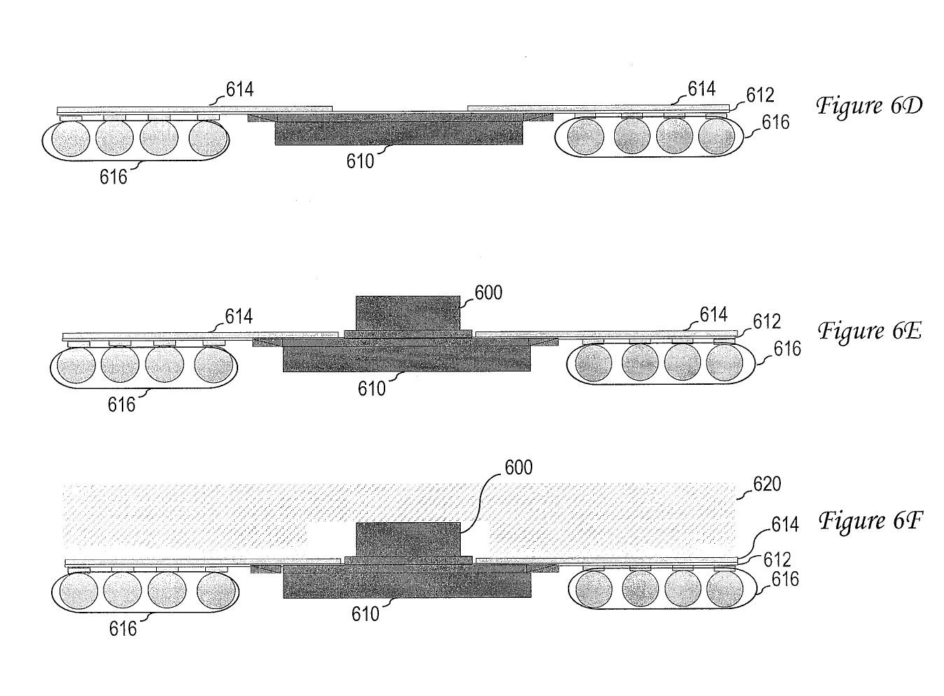

With reference now to FIG. 5, there is illustrated a high level logical flowchart of a second exemplary process for fabricating an integrated circuit package incorporating auxiliary integrated circuitry. To promote understanding of the process shown in FIG. 5, which applies the principles disclosed herein to film-based packaging, additional reference is made to FIGS. 6A-6F, which depict a film-based integrated circuit package at various stages of the fabrication process of FIG. 5.

The process of FIG. 5 begins at block 500 and then proceeds in parallel to blocks 502-506, which depicts the packaging of the primary circuitry chip, and to blocks 510-512, which depicts the packaging of the auxiliary circuitry chip. Referring first to the block 502 and to FIG. 6A, a primary circuitry chip 600, which is carried on a common substrate 602 with test logic 604, is packaged, for example, as a film-based or other “coreless” chip scale package (CSP) having an integrated land grid array (LGA). Primary circuitry chip 600 is then subjected to functional and burn-in testing by applying signals to test circuitry 604 and reading out signals from the primary circuitry chip 600 (block 504) via the integrated LGA. As depicted at block 506 and in FIGS. 6B-6C, assuming primary circuitry chip 600 passes the functional and burn-in testing, primary circuitry chip 600 is excised from substrate 602 at the die boundary by cutting thru the film or coreless material with a laser or mechanical blade. If necessary, packaged primary circuitry chip 600 is then shipped to the final package assembly location.

Referring now to block 510 and FIG. 6D, an auxiliary circuitry chip 610 (e.g., an Application Specific Integrated Circuit (ASIC)) is packaged in a film-based or other coreless “cavity down” package having a thin organic multilayer film containing package interconnect circuitry 612, that is bonded to one or more stiffeners 614 to provide structural integrity, and a ball grid array (BGA) 616 (or land grid array (LGA), not shown) that supports connectivity to external circuitry, such as a circuit card or circuit board. Stiffeners 614 can advantageously be formed of copper or other material that is highly electrically and thermally conductive. Auxiliary circuitry chip 610 is then subjected to functional and burn-in testing by applying signals to BGA 604 (or a LGA) and reading out signals from auxiliary circuitry chip 610 (block 512).

Following block 512, the process proceeds to block 520, which depicts assembly of primary circuitry chip 600 to the film based or coreless circuit package. As shown in FIG. 6E, primary circuitry chip 600 is preferably assembled vertically stacked with auxiliary circuitry chip 610 with the contacts of primary circuitry chip 600 in contact with the contacts of auxiliary circuitry chip 610. Thereafter, as illustrated at block 522 and in FIG. 6F, an application-dependent thermal assembly (or heat sink) 620 is attached over primary circuitry chip 600.

In addition to the advantages previously described, the embodiment of FIG. 5 provides an inexpensive package that has a thin thermal interface between stiffeners 614 and the chips 600, 610, enabling single sided cooling similar to that used in single chip packages. The use of pure copper planes or similar material for stiffeners 614 permits them to be laser drilled very cost effectively, supports leading edge C4 pitch, and effectively distributes power to primary circuitry chip 600.

As has been described, in some embodiments, an integrated circuit package includes a package core and a primary circuitry chip mounted on the package core. The primary circuitry chip has an active surface in which the core circuitry is fabricated. The active surface of the primary circuitry chip faces the package core and includes contacts. The integrated circuit package further includes an auxiliary circuit chip assembled to the package core and having contacts facing and electrically connected to the contacts of the primary circuitry chip.

In at least some embodiments, an integrated circuit package includes a package having a first surface with a cavity therein and an opposing second surface. A primary circuitry chip is mounted on the first surface of the package. The primary circuitry chip has an active surface in which the primary circuitry is fabricated. The active surface of the primary circuitry chip faces the package core and includes contacts. An auxiliary circuit chip is disposed in the cavity of the package core and has contacts facing and electrically connected to the contacts of the primary circuitry chip.

In at least some embodiments, an integrated circuit package includes a film based or coreless substrate, an electrically and thermally conductive stiffener attached to the film based or coreless substrate, a primary circuitry chip mounted on the film based or coreless substrate, and an auxiliary circuit chip assembled to the film based or coreless substrate. The primary circuitry chip has an active surface in which the core circuitry is fabricated. The active surface of the primary circuitry chip faces the film based or coreless substrate and includes contacts. The auxiliary circuit chip also has contacts facing and electrically connected to the contacts of the primary circuitry chip thru vias in the film based or coreless substrate.

In at least some embodiments, integrated circuit package can be made according to a method including partitioning an integrated circuit design into primary circuitry and auxiliary circuitry, fabricating the core circuitry in a primary circuitry chip and fabricating the auxiliary circuitry in an auxiliary circuitry chip, and assembling the primary circuitry chip and the auxiliary circuitry chip to a package with the contacts of the primary circuitry chip and the auxiliary circuitry chip facing each other.

While the present invention has been particularly shown as described with reference to one or more preferred embodiments, it will be understood by those skilled in the art that various changes in form and detail may be made therein without departing from the spirit and scope of the invention.

What is claimed is:

1. An integrated circuit package, comprising:
a package core;
a primary circuitry chip mounted on the package core, the primary circuitry chip having an active surface in which the core circuitry is fabricated, wherein the active surface of the primary circuitry chip faces the package core and includes contacts; and
an auxiliary circuit chip assembled to the package core and having contacts facing and electrically connected to the contacts of the primary circuitry chip.

2. The integrated circuit package of claim 1, wherein:
auxiliary circuitry in the auxiliary circuitry chip has a larger minimum key feature size indicative of a more mature process technology than that of the minimum key feature size in the primary circuitry chip.

3. The integrated circuit package of claim 1, wherein:
the package core has a first surface and an opposing second surface;
the primary circuitry chip is mounted on the first surface of the package core;
the package core has a cavity formed in the first surface; and
the auxiliary circuit chip is disposed in the cavity of the package core.

4. The integrated circuit package of claim 3, and further comprising:
a via formed through the package core and electrically connected to the primary circuitry chip;
a package connector electrically connected to the via.

5. The integrated circuit package of claim 3, and further comprising:
a buildup layer over the auxiliary circuit chip and the package core;
micro-vias that extend through the buildup layer and electrically connect the contacts of the auxiliary circuit chip and the primary circuitry chip.

6. The integrated circuit package of claim 1, wherein:
the package contains a film or coreless substrate; and
the integrated circuit package further includes an electrically and/or thermally conductive stiffener attached to the film or coreless substrate.

7. The integrated circuit package of claim 6, and further comprising a thermal cap over the primary circuitry chip and contacting the stiffener.

8. The integrated circuit package of claim 6, and further comprising a plurality of package connectors coupled to the film or coreless substrate.

9. An integrated circuit package, comprising:
a package core having a first surface and an opposing second surface, wherein the first surface has a cavity therein;
a primary circuitry chip mounted on the first surface of the package core, the primary circuitry chip having an active surface in which the core circuitry is fabricated, wherein the active surface of the primary circuitry chip faces the package core and includes contacts; and
an auxiliary circuit chip disposed in the cavity of the package core and having contacts facing and electrically connected to the contacts of the primary circuitry chip.

10. The integrated circuit package of claim 9, wherein:
auxiliary circuitry in the auxiliary circuitry chip has a larger minimum key feature size than that of the primary circuitry in the primary circuitry chip.

11. The integrated circuit package of claim 10, and further comprising:
a via formed through the package and electrically connected to the primary circuitry chip; and
a package connector electrically connected to the via.

12. The integrated circuit package of claim 11, and further comprising:
a buildup layer over the auxiliary circuit chip and the package core;
micro-vias that extend through the buildup layer and electrically connect the contacts of the auxiliary circuit chip and the primary circuitry chip.

13. An integrated circuit package, comprising:
a thin-film flexible substrate or a coreless substrate;
an electrically and thermally conductive stiffener attached to the thin-film flexible substrate;
a primary circuitry chip mounted on the thin-film flexible substrate or coreless substrate, the primary circuitry chip having an active surface in which the core circuitry is fabricated, wherein the active surface of the primary circuitry chip faces the thin-film flexible substrate and includes contacts; and
an auxiliary circuit chip assembled to the thin-film flexible substrate or coreless substrate and having contacts facing and electrically connected to the contacts of the primary circuitry chip.

14. The integrated circuit package of claim 13, wherein:
auxiliary circuitry in the auxiliary circuitry chip has a larger minimum line size than that of the core circuitry in the primary circuitry chip.

15. The integrated circuit package of claim 14, and further comprising a thermal cap over the primary circuitry chip and contacting the stiffener.

16. The integrated circuit package of claim 13, and further comprising a plurality of package connectors coupled to the thin-film substrate.

17. A method of packaging integrated circuitry, the method comprising:
partitioning an integrated circuit design into core circuitry and auxiliary circuitry;
fabricating the core circuitry in a primary circuitry chip and fabricating the auxiliary circuitry in an auxiliary circuitry chip, each of the primary circuitry chip and auxiliary circuitry chip having respective contacts; and
assembling the primary circuitry chip and the auxiliary circuitry chip to a package with the contacts of the primary circuitry chip and the auxiliary circuitry chip facing each other.

18. The method of claim 17, wherein the partitioning includes partitioning input/output functionality of the integrated circuit design within the auxiliary circuitry.

19. The method of claim 17, wherein fabricating the auxiliary circuitry in the auxiliary circuitry chip comprises fabricating the auxiliary circuitry utilizing an older process technology than utilized to fabricate the core circuitry in the primary circuitry chip.

20. The method of claim 17, wherein the assembling includes:
forming a cavity in an insulative package core; and
placing the auxiliary circuit chip in the cavity of the insulative package core.

21. The method of claim 20, wherein the assembling further includes:
forming a package through hole through the package core;
forming a via in the package through hole; and
attaching a connector to the via.

22. The method of claim 20, wherein the assembling includes:
forming a buildup layer over the auxiliary circuit chip and the package core;
forming openings in the buildup layer to the contacts of the auxiliary circuit chip;
forming micro-vias in the openings in the buildup layer that are electrically connected to the contacts of the auxiliary circuit chip; and
attaching the primary circuitry chip with its contacts electrically connected to the micro-vias.

23. The method of claim 17, wherein the assembling comprises assembling the primary circuitry chip and the auxiliary circuitry chip to a film-based flex circuit package.

24. The method of claim 17, wherein the assembling comprises attaching a thermal cap over the primary circuitry chip.
